(19) United States
(12) Patent Application Publication
(10) Pub. No.: US 2026/0068585 A1
(43) Pub. Date: Mar. 5, 2026

(54) BONDING SYSTEM

(71) Applicant: Tokyo Electron Limited, Tokyo (JP)

(72) Inventor: Katsuhiro IINO, Koshi City (JP)

(73) Assignee: Tokyo Electron Limited, Tokyo (JP)

(21) Appl. No.: 19/313,929

(22) Filed: Aug. 29, 2025

(30) Foreign Application Priority Data
Aug. 30, 2024 (JP) 2024-148193

(51) Int. Cl. H01L 21/67; H01L 21/66

(52) U.S. Cl. CPC H01L 21/67132

(57) ABSTRACT

A bonding system includes a processing station that performs a required processing on a first substrate and a second substrate; and a carry-in/out station that carries the first substrate, the second substrate, and a combined substrate, which is formed by bonding the first substrate and the second substrate, to/from the processing station. The processing station includes a transfer device that transfers the first substrate, the second substrate, and the combined substrate; a delivery module that delivers the first substrate, the second substrate, and the combined substrate between the carry-in/out station and the transfer device; a coating apparatus that applies an adhesive to the first substrate; a bonding apparatus that bonds the first substrate and the second substrate; and a heat treating apparatus that heat-treats the first substrate, the second substrate, and the combined substrate. The heat treating apparatus and the bonding apparatus are arranged in a stacked manner.

### CROSS-REFERENCE TO RELATED APPLICATION

This application claims the benefit of Japanese Patent Application No. 2024-148193 filed on Aug. 30, 2024, the entire disclosure of which is incorporated herein by reference.

### TECHNICAL FIELD

The various aspects and embodiments described herein pertain generally to a bonding system.

### BACKGROUND

In recent years, in a manufacturing process for semiconductor devices, a processing target substrate, such as a silicon wafer or a compound semiconductor wafer, has an increased diameter while being thinner. The thin substrate with such a large diameter may bend and crack when it is transferred and polished. For this reason, a supporting substrate such as a glass substrate is bonded to the processing target substrate to reinforce the processing target substrate.

The bonding of the processing target substrate and the supporting substrate is performed by using a bonding apparatus. There is known a bonding system including, in addition to the bonding apparatus, a transfer device for transferring the processing target substrate and the supporting substrate, a coating apparatus for applying an adhesive to the processing target substrate, a heat treating apparatus for heating the processing target substrate coated with the adhesive, and the like, which are integrated as a single structure (see Patent Document 1).
Patent Document 1: Japanese Patent Laid-open Publication No. 2015-046531

### SUMMARY

In an exemplary embodiment, a bonding system includes a processing station and a carry-in/out station. The processing station is configured to perform a required processing on a first substrate and a second substrate. The carry-in/out station is configured to carry the first substrate, the second substrate, and a combined substrate, which is formed by bonding the first substrate and the second substrate, to/from the processing station. The processing station includes a transfer device, a delivery module, a coating apparatus, a bonding apparatus and a heat treating apparatus. The transfer device is configured to transfer the first substrate, the second substrate, and the combined substrate. The delivery module is configured to deliver the first substrate, the second substrate, and the combined substrate between the carry-in/out station and the transfer device. The coating apparatus is configured to apply an adhesive to the first substrate. The bonding apparatus is configured to bond the first substrate coated with the adhesive and the second substrate to form the combined substrate. The heat treating apparatus is configured to heat-treat the first substrate, the second substrate, and the combined substrate. The heat treating apparatus and the bonding apparatus are arranged in a stacked manner.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating an example configuration of a bonding system according to an exemplary embodiment;

FIG. 2 is a schematic side view of a combined substrate according to the exemplary embodiment;

FIG. 3 is a cross sectional view taken along a line A-A in FIG. 1;

FIG. 4 is a cross sectional view taken along a line B-B in FIG. 1;

FIG. 5 is a cross sectional view taken along a line C-C in FIG. 1;

FIG. 6 is a cross sectional view taken along a line D-D in FIG. 1;

FIG. 7 is a schematic cross sectional view illustrating an example configuration of a coating apparatus according to the exemplary embodiment;

FIG. 8 is a schematic cross sectional view illustrating an example configuration of a heat treating apparatus according to the exemplary embodiment;

FIG. 9 is a schematic plan view illustrating the example configuration of the heat treating apparatus according to the exemplary embodiment;

FIG. 10 is a schematic cross sectional view illustrating an example configuration of a bonding apparatus according to the exemplary embodiment;

FIG. 11 is a schematic cross sectional view illustrating the example configuration of the bonding apparatus according to the exemplary embodiment;

FIG. 12 is a schematic side view illustrating an example configuration of a second transfer device according to the exemplary embodiment;

FIG. 13 is a schematic side view illustrating another example configuration of the second transfer device according to the exemplary embodiment; and

FIG. 14 is a flowchart illustrating a sequence of a processing performed by the bonding system according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a bonding system according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction.

In recent years, in a manufacturing process for semiconductor devices, a processing target substrate, such as a silicon wafer or a compound semiconductor wafer, has an increased diameter while being thinner. The thin substrate with such a large diameter may bend and crack when it is transferred and polished. For this reason, a supporting substrate such as a glass substrate is bonded to the processing target substrate to reinforce the processing target substrate.

The bonding of the processing target substrate and the supporting substrate is performed by using a bonding apparatus. In the bonding apparatus, after the supporting substrate and the processing target substrate are held by, for example, an upper chuck and a lower chuck, respectively, the upper chuck or the lower chuck is moved to press the processing target substrate and the supporting substrate against each other. A surface of the processing target substrate or supporting substrate is coated with an adhesive, and the processing target substrate and the supporting substrate are bonded to each other by being pressed as stated above.

The present disclosure also describes a bonding system including, in addition to the bonding apparatus, a transfer device for transferring the processing target substrate and the supporting substrate, a coating apparatus for coating the processing target substrate with an adhesive, a heat treating apparatus for heating the processing target substrate coated with the adhesive, and the like, which are integrated as a single structure.

Meanwhile, in the aforementioned prior art, there is still a room for improvement in terms of reducing a footprint, which refers to a proportion of a floor area in a clean room occupied by the bonding system.

In this regard, there is a demand for a technology capable of overcoming the aforementioned problems and reducing the footprint of the bonding system.

### Outline of Bonding System

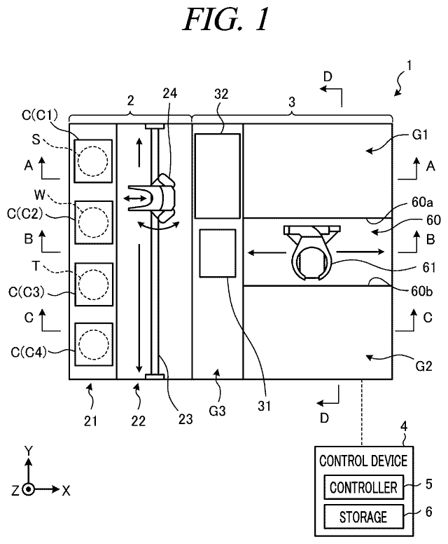

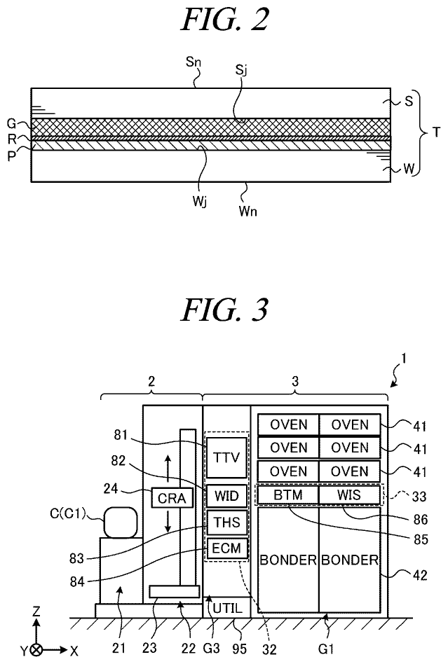

First, an outline of a bonding system 1 according to an exemplary embodiment will be explained with reference to FIG. 1 and FIG. 2. FIG. 1 is a schematic plan view illustrating an example configuration of the bonding system 1 according to the exemplary embodiment, and FIG. 2 is a schematic side view of a combined substrate T according to the exemplary embodiment.

The bonding system 1 shown in FIG. 1 forms a combined substrate T by bonding a support substrate S and a device substrate W with an adhesive G, a protective agent P, and a release agent R therebetween, as shown in FIG. 2. The support substrate S is an example of a first substrate, and the device substrate W is an example of a second substrate.

The device substrate W is a semiconductor substrate, such as a silicon wafer or a compound semiconductor wafer, on which multiple electronic circuits are formed, and its plate surface on which the electronic circuits are formed is referred to as a bonding surface Wj to be bonded to the support substrate S.

After the device substrate W is bonded to the support substrate S, a non-bonding surface Wn of the device substrate W, which is a plate surface opposite the bonding surface Wj, is ground, whereby the device substrate W is thinned.

The support substrate S, which has approximately the same diameter as the device substrate W, supports the device substrate W. A semiconductor substrate such as a silicon wafer or a compound semiconductor wafer, as well as a glass substrate, may be used as the support substrate S.

The adhesive G is applied to a bonding surface Sj of the support substrate S to be bonded to the device substrate W. The adhesive G is, by way of example, a thermosetting resin-based adhesive. Here, thermosetting refers to a property of a material that is difficult to transform at a room temperature (e.g., about 20° C.), becomes soft and easy to mold when heated, and hardens with the progress of polymerization when further heated, without returning to its original state.

The adhesive G used in the bonding system 1 has a softening temperature of about 120° C. to 140° C. and a hardening temperature of about 180° C.

The protective agent P is applied to the bonding surface Wj of the device substrate W. The protective agent P is applied to the bonding surface Wj of the device substrate W for the purpose of protecting circuits and bumps formed on the bonding surface Wj of the device substrate W.

A material with lower adhesive strength and lower viscosity than the adhesive G is used as the protective agent P. Also, the protective agent P is soluble in an organic solvent such as thinner, and does not harden even when it is heated.

The release agent R is applied to a surface of the protective agent P. The release agent R is applied for the purpose of smooth separation of the device substrate W and the support substrate S when separating the combined substrate T into the device substrate W and the support substrate S.

A material having lower adhesive strength and lower viscosity than the adhesive G is used as the release agent R. Also, the release agent R is soluble in an organic solvent such as thinner, and does not harden even when it is heated. Further, the release agent R has lower adhesive strength than the protective agent P.

Since the adhesive strength of the release agent R is lower than that of the adhesive G, if the release agent R is applied thick, the bonding strength of the combined substrate T would be weakened. For this reason, it is desirable to apply the release agent R thin.

Reference is made back to FIG. 1. As depicted in FIG. 1, the bonding system 1 is equipped with a carry-in/out station 2 and a processing station 3. The carry-in/out station 2 and the processing station 3 are connected as a single structure in this order along the positive X-axis direction.

The carry-in/out station 2 includes a placement table 21 and a first transfer section 22. The placement table 21 is a place where a plurality of cassettes C each of which accommodates a multiple number of (e.g., 25 sheets of) substrates horizontally is arranged.

Of the plurality of cassettes C, a cassette C1 accommodates, for example, support substrates S, a cassette C2 accommodates, for example, device substrates W, and a cassette C3 accommodates, for example, combined substrates T.

Of the plurality of cassettes C, a cassette C4 accommodates, for example, a substrate with a defect. Here, the number of the cassettes C placed on the placement table 21 is not limited to the shown example.

The first transfer section 22 is provided adjacent to the positive X-axis side of the placement table 21, for example. This first transfer section 22 is provided with a transfer path 23 extending in the Y-axis direction, and a first transfer device 24 configured to be movable along this transfer path 23. The first transfer device 24 is an example of another transfer device. The first transfer device 24 is movable in the X-axis direction as well as in the Y-axis direction and pivotable around a Z-axis.

The first transfer device 24 serves to transfer the device substrates W, the support substrates S, and the combined substrates T between the cassettes C placed on the placement table 21 and a third processing block G3 of the processing station 3 to be described later.

The processing station 3 has, for example, three processing blocks G1, G2, and G3. By way of example, the first processing block G1 is located on the rear side (positive Y-axis side of FIG. 1) of the processing station 3.

The second processing block G2 is located on, for example, the front side (negative Y-axis side of FIG. 1) of the processing station 3. Detailed configurations of the first processing block G1 and the second processing block G2 will be described later.

The third processing block G3 is located on, for example, the carry-in/out station 2 side (the negative X-axis side of FIG. 1) of the processing station 3. The third processing block G3 has a delivery module 31 and a first inspection module 32. The first inspection module 32 is an example of an inspection module.

The delivery module 31 is located between the first transfer section 22 and a second transfer section 60 to be described later. In the delivery module 31, the device substrate W, the support substrate S, and the combined substrate T are transferred between the first transfer device 24 located in the first transfer section 22 and a second transfer device 61 located in the second transfer section 60.

That is, the delivery module 31 is accessible from both the first transfer device 24 and the second transfer device 61. On the other hand, the first inspection module 32 is not accessible from the second transfer device 61, and only accessible from the first transfer device 24. Detailed configurations of the delivery module 31 and the first inspection module 32 will be explained later.

The second transfer section 60 is located in a region surrounded by the first processing block G1, the second processing block G2, and the third processing block G3. The second transfer section 60 is an example of a transfer section. The second transfer section 60 is provided with the second transfer device 61. The second transfer device 61 is an example of a transfer device. The second transfer device 61 has a transfer arm 61c (see FIG. 12) configured to be movable in a vertical direction and a horizontal direction and pivotable around a vertical axis, for example.

This second transfer device 61 is moved within the second transfer section 60 to transfer the device substrate W, the support substrate S, and the combined substrate T (e.g., wafer) to required apparatuses within the first processing block G1, the second processing block G2, and the third processing block G3 that are adjacent to the transfer section 60.

Further, the bonding system 1 is equipped with a control device 4. The control device 4 is configured to control an operation of the bonding system 1. The control device 4 is, for example, a computer, and includes a controller 5 and a storage 6.

The controller 5 includes a microcomputer having a central processing unit (CPU), a read only memory (ROM), a random access memory (RAM), input/output ports, etc., and various types of circuits. The CPU of the microcomputer reads and executes a program stored in the ROM, thus implementing a control to be described later. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The storage 6 is implemented by, for example, a semiconductor memory device such as a RAM or a flash memory, or a storage device such as a hard disk or an optical disk.

The program that is executed by the controller 5 has been recorded on a computer-readable recording medium, and may be installed from that recording medium into the storage 6 of the control device 4. The computer-readable recording medium may be, by way of non-limiting example, a hard disk (HD), a flexible disk (FD), a compact disk (CD), a magnetic optical disk (MO), a memory card, or the like.

### Details of Bonding System

Now, a detailed configuration of the bonding system 1 according to the exemplary embodiment will be explained with reference to FIG. 3 to FIG. 6 in addition to FIG. 1 and FIG. 2. FIG. 3 to FIG. 6 are cross sectional views taken along lines A-A, B-B, C-C and D-D of FIG. 1, seen from the directions indicated by the arrows.

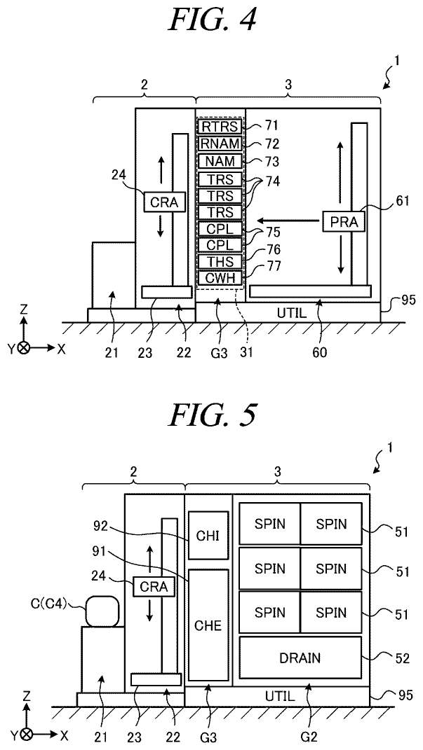

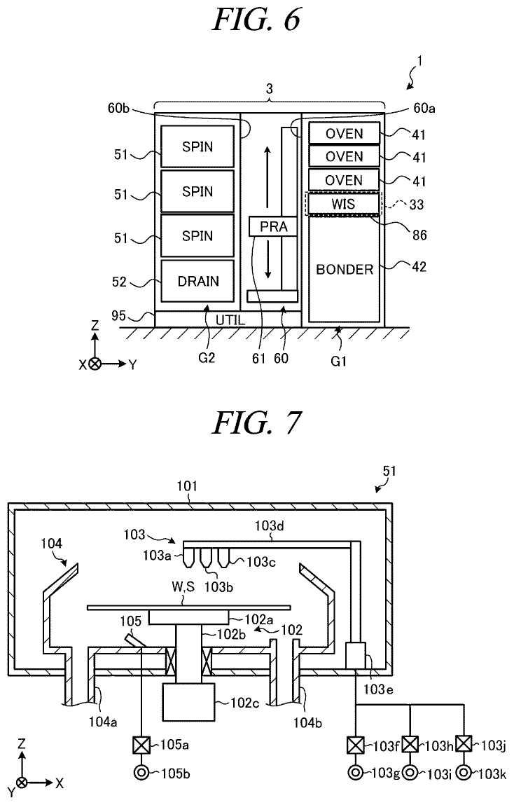

That is, FIG. 3 is a diagram illustrating a configuration of the first processing block G1, the first inspection module 32, and a second inspection module 33 shown in FIG. 1. FIG. 4 is a diagram illustrating a configuration of the delivery module 31 and the second transfer section 60 shown in FIG. 1. FIG. 5 is a diagram illustrating a configuration of the second processing block G2 and the third processing block G3 shown in FIG. 1, and FIG. 6 is a diagram illustrating a configuration of the first processing block G1, the second transfer section 60, and the second processing block G2 shown in FIG. 1.

As depicted in FIG. 6, the first processing block G1 is located on a first side 60a of the second transfer section 60. Also, as shown in FIG. 3 and FIG. 6, the first processing block G1 has a multiple number of heat treating apparatuses 41, a multiple number of bonding apparatuses 42, and the second inspection module 33. In the drawings of the present disclosure, the heat treating apparatus 41 is denoted by “OVEN”, and the bonding apparatus 42 is denoted by “BONDER”.

The heat treating apparatus 41 is a device that heats the support substrate S (see FIG. 2), the device substrate W (see FIG. 2), and the combined substrate T (see FIG. 2) to a preset temperature. The bonding apparatus 42 is a device that bonds the device substrate W and the support substrate S with the protective agent P (see FIG. 2), the release agent R (see FIG. 2), and the adhesive G (see FIG. 2) therebetween.

As illustrated in FIG. 3, the bonding system 1 according to the exemplary embodiment is equipped with, for example, eight heat treating apparatuses 41 and two bonding apparatuses 42. In the exemplary embodiment, the two bonding apparatuses 42 are arranged in a lower portion of the first processing block G1 along the X-axis direction.

In the example of FIG. 3, etc., the two bonding apparatuses 42 are arranged along the horizontal direction. However, the present disclosure is not limited thereto, and three or more bonding apparatuses 42, for example, may be arranged along the vertical direction.

Further, in the exemplary embodiment, the heat treating apparatuses 41 and the bonding apparatuses 42 are arranged in a stacked manner. By way of example, in the present exemplary embodiment, the heat treating apparatuses 41 are arranged above the bonding apparatuses 42. Specifically, in the present exemplary embodiment, three heat treating apparatuses 41 are stacked above one bonding apparats 42.

In the example of FIG. 3, etc., the three heat treating apparatuses 41 are stacked above the single bonding apparatus 42. However, the present disclosure is not limited thereto. By way of example, one, two, or more than three heat treating apparatuses 41 may be stacked above the single bonding apparatus 42.

Furthermore, in the present disclosure, the heat treating apparatus 41 is not limited to being arranged above the bonding apparatus 42, but may be arranged below the bonding apparatus 42. Detailed configurations of the heat treating apparatus 41 and the bonding apparatus 42 will be explained later.

As illustrated in FIG. 3, the second inspection module 33 is located between the heat treating apparatus 41 and the bonding apparatus 42 in the first processing block G1, for example. The second inspection module 33 has a film thickness measurement apparatus 85 and a periphery inspection apparatus 86. In the drawings of the present disclosure, the film thickness measurement apparatus 85 is denoted by “BTM”, and the periphery inspection apparatus 86 is denoted by “WIS”.

The film thickness measurement apparatus 85 is a device that measures the film thickness of the adhesive G applied on the support substrate S as well as the uniformity of this film thickness. The periphery inspection apparatus 86 is a device that measures a state of the adhesive G removed from a periphery of the support substrate S (including, for example, dimensions of a region from which the adhesive G has been removed, and any non-uniformity in such dimensions).

As illustrated in FIG. 6, the second processing block G2 is located on a second side 60b of the second transfer section 60. The second side 60b is the side opposite the first side 60a.

As shown in FIG. 5 and FIG. 6, the second processing block G2 has a multiple number of coating apparatuses 51 and one drain apparatus 52. In the drawings of the present disclosure, the coating apparatus 51 is denoted by “SPIN”, and the drain apparatus 52 is denoted by “DRAIN.”

The coating apparatus 51 is a device that coats the support substrate S (see FIG. 2) with the adhesive G (see FIG. 2) and coats the device substrate W (see FIG. 2) with the protective agent P (see FIG. 2) and the release agent R (see FIG. 2). The drain apparatus 52 is a device that drains various processing liquids used in the coating apparatuses 51 to the outside.

As depicted in FIG. 5, the bonding system 1 according to the exemplary embodiment is provided with, for example, six coating apparatuses 51 and one drain apparatus 52. Further, in the present exemplary embodiment, the one drain apparatus 52 is located in a lower portion of the second processing block G2.

In the present exemplary embodiment, the coating apparatuses 51 are disposed above the drain apparatus 52. Specifically, in the present exemplary embodiment, two sets of three coating apparatuses 51, six in total, are stacked above the single drain apparatus 52. Detailed configuration of the coating apparatus 51 will be elaborated later.

As shown in FIG. 4, the delivery module 31 has an inversion delivery apparatus 71, an inversion alignment apparatus 72, an alignment apparatus 73, a multiple number of (three in the shown example) delivery apparatuses 74, a multiple number of (two in the shown example) cooling apparatuses 75, a temporary placement apparatus 76, and a jig housing apparatus 77.

In the drawings of the present disclosure, the inversion delivery apparatus 71 is denoted by “RTRS”; the inversion alignment apparatus 72, “RNAM”; the alignment apparatus 73, “NAM”; the delivery apparatus 74, “TRS”; and the cooling apparatus 75, “CPL”.

In the drawings of the present disclosure, the temporary placement apparatus 76 is denoted by “THS”, and the jig housing apparatus 77 is labeled as “CWH”. Furthermore, in the drawings of the present disclosure, the first transfer device 24 is denoted by “CRA”, and the second transfer device 61 is labeled as “PRA”.

The inversion delivery apparatus 71 is a device in which the device substrate W, the support substrate S or the combined substrate T transferred between the first transfer device 24 and the second transfer device 61 is temporarily placed. The inversion delivery apparatus 71 further has a mechanism for inverting the device substrate W, the support substrate S or the combined substrate T placed therein.

The inversion alignment apparatus 72 is a device that performs alignment of the support substrate S. The inversion alignment apparatus 72 has, for example, a holder configured to attract and hold the support substrate S and rotate it, a detector configured to detect a position of a notch of the support substrate S, and an inverting mechanism configured to invert the support substrate S held by the holder.

The inversion alignment apparatus 72 detects the position of the notch of the support substrate S with the detector while rotating the support substrate S attracted to and held by the holder, and is capable of adjusting a direction of the support substrate S in the horizontal direction by adjusting the position of the notch thereof. Also, the inversion alignment apparatus 72 is capable of inverting front and rear surfaces of the support substrate S upside down with the inverting mechanism.

The alignment apparatus 73 is a device that performs alignment of the device substrate W. The alignment apparatus 73 has, for example, a holder configured to attract and hold the device substrate W and rotate it, and a detector configured to detect the position of a notch of the device substrate W.

The alignment apparatus 73 detects the position of the notch of the device substrate W with the detector while rotating the device substrate W attracted to and held by the holder, and is capable of adjusting a direction of the device substrate W in the horizontal direction by adjusting the position of the notch thereof.

The delivery apparatus 74 is a device in which the device substrate W, the support substrate S or the combined substrate T that is transferred between the first transfer device 24 and the second transfer device 61 is temporarily placed. The cooling apparatus 75 is a device that cools the combined substrate T to a required temperature.

The temporary placement apparatus 76 is a device configured to temporarily accommodate the device substrate W, the support substrate S, or the combined substrate T when the position of these substrates during or after the transfer is significantly deviated from a specified position, in order to correct such positional deviation. The jig housing apparatus 77 is a device in which various types of jigs such as dummy substrates are accommodated.

As shown in FIG. 3, the first inspection module 32 has a thickness measurement apparatus 81, an ID reader 82, a temporary placement apparatus 83, and a periphery measurement apparatus 84. In the drawings of the present disclosure, the thickness measurement apparatus 81 is denoted by “TTV”; the ID reader 82, “WID”; the temporary placement apparatus 83, “THS”; and the periphery measurement apparatus 84, “ECM”.

The thickness measurement apparatus 81 is a device for measuring unevenness in the thickness of the adhesive G in the combined substrate T. The thickness measurement apparatus 81 measures, for example, a total thickness variation (TTV) of the combined substrate T (a difference between the maximum and minimum thickness values in the entire surface of the combined substrate T).

The ID reader 82 is a device that reads identification information assigned to the support substrate S and the device substrate W. The temporary placement apparatus 83 temporarily accommodates the device substrate W, the support substrate S, or the combined substrate T when the position of these substrates is significantly deviated from the specified position during or after transfer, in order to correct such positional deviation.

The periphery measurement apparatus 84 measures a periphery of the combined substrate T in order to observe the bonding state of the combined substrate T. By way of example, the periphery measurement apparatus 84 may directly measure the periphery of the combined substrate T with a laser displacement meter, or may image the periphery of the combined substrate T from the side with a camera or the like and calculate the dimensions of the periphery from the obtained image.

As illustrated in FIG. 5, the third processing block G3 has a chemical liquid supply apparatus 91 and a cooling apparatus 92 in addition to the aforementioned delivery module 31 (see FIG. 4) and the first inspection module 32 (see FIG. 3). In the drawings of the present disclosure, the chemical liquid supply apparatus 91 is denoted by “CHE” and the cooling apparatus 92 is denoted by “CHI”.

The chemical liquid supply apparatus 91 supplies various types of chemical liquids to various apparatuses (for example, the coating apparatus 51, etc.) of the bonding system 1, for example. The cooling apparatus 92 cools the various types of liquids supplied from the chemical liquid supply apparatus 91 into the bonding system 1, for example.

As shown in FIG. 3 to FIG. 6, a utility section 95 is located at a bottom of the second processing block G2, the third processing block G3, and the second transfer section 60. In the drawings of the present disclosure, the utility section 95 is labeled as “UTIL”. Electrical wiring and gas piping are located in this utility section 95.

Although not shown in FIG. 3 to FIG. 6, a fan filter unit (FFU) and an electrical system may be provided at a ceiling portion of the bonding system 1.

The FFU supplies dry air from which particles or the like have been removed into the bonding system 1 from above. This supplied dry air forms a clean downflow inside the bonding system 1. The electrical system includes, by way of example, a switchboard, a breaker, and an ammeter.

Here, in the prior art bonding system, since the heat treating apparatus and the bonding apparatus are arranged horizontally, the footprint increases. Meanwhile, in the bonding system 1 according to the exemplary embodiment, the heat treating apparatus 41 and the bonding apparatus 42 are stacked inside the bonding system 1, as illustrated in FIG. 3.

Therefore, according to the bonding system 1 of the present exemplary embodiment, the footprint can be reduced as compared to the conventional bonding system.

Furthermore, in the exemplary embodiment, the heat treating apparatus 41 may be disposed above the bonding apparatus 42. This can suppress the temperature of the bonding apparatus 42 from rising excessively due to the heat transferred upwards from the inside of the heat treating apparatus 41. Therefore, according to the exemplary embodiment, a bonding processing in the bonding apparatus 42 can be performed with high precision.

Furthermore, in the exemplary embodiment, the heat treating apparatus 41 and the bonding apparatus 42 may be disposed on the first side 60a of the second transfer section 60, and the coating apparatus 51 may be located on the second side 60b of the second transfer section 60, as illustrated in FIG. 6.

With this configuration, the support substrate S, which has been coated with adhesive G in the coating apparatus 51, and the device substrate W, which has been coated with protective agent P and the release agent R in the coating apparatus 51, can be promptly transferred to the heat treating apparatus 41. Therefore, according to the exemplary embodiment, a post-coating heat treatment can be performed rapidly, so that the adhesive G, the protective agent P, and the release agent R can be applied with high precision.

Furthermore, in the conventional bonding system, since an inversion alignment apparatus is provided in each of the multiple bonding apparatuses, the overall footprint in the bonding apparatuses increases.

Meanwhile, in the bonding system 1 according to the exemplary embodiment, only one inversion alignment apparatus 72 that can be shared by all of the bonding apparatuses 42 is provided in the delivery module 31 of the third processing block G3.

Therefore, according to the bonding system 1 of the present exemplary embodiment, the footprint can be reduced as compared to the conventional bonding system.

Also, in the conventional bonding system, an alignment device is provided in each of the multiple bonding apparatuses, which results in the increase of the overall footprint in the bonding apparatuses.

Meanwhile, in the bonding system 1 according to the exemplary embodiment, only one alignment apparatus 73 that can be shared by all of the bonding apparatuses 42 is disposed in the delivery module 31 of the third processing block G3.

Therefore, according to the bonding system 1 of the present exemplary embodiment, the footprint can be reduced as compared to the conventional bonding system.

Furthermore, in the exemplary embodiment, the cooling apparatus 75 for cooling the combined substrate T may be provided in the delivery module 31 so as to be stacked together with the other apparatuses. This allows the footprint of the bonding system 1 to be further reduced.

Also, in the exemplary embodiment, the first inspection module 32 for inspecting at least one of the support substrate S, the device substrate W, and the combined substrate T may not be accessible from the second transfer device 61 but may be accessible only from the first transfer device 24.

With this configuration, the first inspection module 32 capable of inspecting various types of substrates can be placed inside the bonding system 1 without increasing the footprint of the first processing block G1, the second processing block G2, and the delivery module 31, where other devices need to be placed.

Therefore, according to the exemplary embodiment, the footprint of the bonding system 1 can be further reduced.

In addition, in the present exemplary embodiment, the thickness measurement apparatus 81 for measuring the unevenness in the thickness of the adhesive G in the combined substrate T may be provided in the first inspection module 32, which is accessible only from the first transfer device 24.

With this configuration, the thickness measurement apparatus 81 can be placed inside the bonding system 1 without increasing the footprint of the first processing block G1, the second processing block G2, and the delivery module 31, where other devices need to be placed.

Therefore, according to the exemplary embodiment, the footprint of the bonding system 1 can be further reduced.

In addition, in the exemplary embodiment, the ID reader 82 for reading the identification information of the device substrate W and the support substrate S may be provided in the first inspection module 32 accessible only from the first transfer device 24.

With this configuration, the ID reader 82 can be placed inside the bonding system 1 without increasing the footprint of the first processing block G1, the second processing block G2, and the delivery module 31, where other devices need to be placed.

Therefore, according to the present exemplary embodiment, the footprint of the bonding system 1 can be further reduced.

### Coating Apparatus

Now, a configuration of the coating apparatus 51 will be explained with reference to FIG. 7. FIG. 7 is a schematic cross sectional view illustrating an example configuration of the coating apparatus 51. As shown in FIG. 7, the coating apparatus 51 is equipped with a chamber 101, a substrate holding mechanism 102, a liquid supply 103, a recovery cup 104, and a periphery cleaner 105.

The chamber 101 houses the substrate holding mechanism 102, the liquid supply 103, the recovery cup 104, and the periphery cleaner 105. A non-illustrated FFU is provided at a ceiling portion of the chamber 101. The FFU forms a clean downflow inside the chamber 101.

The substrate holding mechanism 102 is provided at the approximate center of the chamber 101, and has a holder 102a, a support column 102b, and a driver 102c.

The holder 102a is, by way of non-limiting example, a porous chuck, and serves to attract and hold the device substrate W and the support substrate S. The support column 102b is a vertically extending member, and its base end is rotatably supported by the driver 102c, and its tip end supports the holder 102a horizontally.

The driver 102c rotates the support column 102b around a vertical axis. The substrate holding mechanism 102 rotates the support column 102b using the driver 102c, thereby rotating the holder 102a supported by the support column 102b.

As a result, the device substrate W and the support substrate S held by the holder 102a are rotated. Further, the device substrate W and the support substrate S are held by the substrate holding mechanism 102 with their bonding surfaces Wj (see FIG. 2) and Sj (see FIG. 2) facing upwards.

The liquid supply 103 supplies the adhesive G (see FIG. 2) to the support substrate S held by the substrate holding mechanism 102, and supplies the protective agent P (see FIG. 2) and the release agent R (see FIG. 2) to the device substrate W held by the substrate holding mechanism 102.

The liquid supply 103 has nozzles 103a, 103b, and 103c, an arm 103d, and a rotating/elevating mechanism 103e. The arm 103d holds the nozzles 103a, 103b, and 103c. The rotating/elevating mechanism 103e rotates and moves the arm 103d up and down.

The nozzle 103a is connected to an adhesive source 103g via a valve 103f, and discharges the adhesive G supplied from the adhesive source 103g onto the support substrate S. The nozzle 103b is connected to a protective agent source 103i via a valve 103h, and discharges the protective agent P supplied from the protective agent source 103i onto the device substrate W.

The nozzle 103c is connected to a release agent source 103k via a valve 103j, and discharges the release agent R supplied from the release agent source 103k onto the device substrate W.

The recovery cup 104 is disposed to surround the holder 102a, and serves to collect the adhesive G, the protective agent P, and the release agent R scattered from the support substrate S and the device substrate W as the holder 102a is rotated.

A drain port 104a is formed at the bottom of the recovery cup 104. The adhesive G, the protective agent P, and the release agent R collected by the recovery cup 104 are drained from this drain port 104a to the outside of the coating apparatus 51.

In addition, an exhaust port 104b is formed at the bottom of the recovery cup 104 to exhaust the downflow gas supplied from the non-illustrated FFU to the outside of the coating apparatus 51.

The periphery cleaner 105 is configured to remove the adhesive G adhering to a peripheral portion of the support substrate S. The periphery cleaner 105 is provided below the support substrate S held by the substrate holding mechanism 102, for example, at the bottom of the recovery cup 104.

The periphery cleaner 105 is connected to a chemical liquid source 105b via a valve 105a, and discharges the chemical liquid supplied from the chemical liquid source 105b, here, an organic solvent such as thinner, toward the peripheral portion of the rear surface of the support substrate S.

In the coating apparatus 51, the substrate holding mechanism 102 holds and rotates the support substrate S, and the periphery cleaner 105 supplies the organic solvent to the peripheral portion of the rear surface of the support substrate S being rotated. The organic solvent supplied to the periphery of the rear surface of the support substrate S flows from the rear surface of the support substrate S to a front surface thereof, dissolving the adhesive G adhering to the peripheral portion of the support substrate S to thereby remove it.

### Heat Treating Apparatus

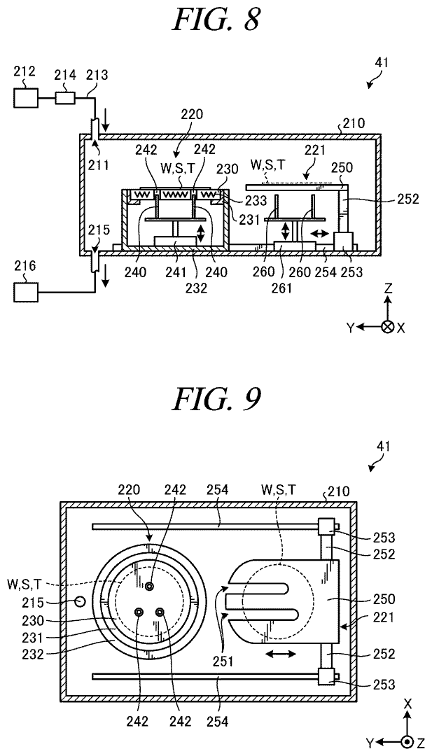

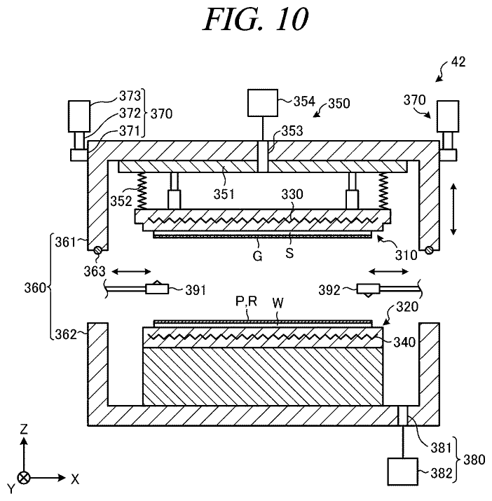

Now, a configuration of the heat treating apparatus 41 according to the exemplary embodiment will be elaborated with reference to FIG. 8 and FIG. 9. FIG. 8 is a schematic cross sectional view illustrating an example configuration of the heat treating apparatus 41, and FIG. 9 is a schematic plan view illustrating the example configuration of the heat treating apparatus 41.

As shown in FIG. 8, the heat treating apparatus 41 has a chamber 210 with a sealable inside. A carry-in/out opening (not shown) for the device substrate W and the support substrate S is formed in a side surface of the chamber 210 on the second transfer section 60 (see FIG. 1) side, and an opening/closing shutter (not shown) is provided at this carry-in/out opening.

A gas supply port 211 is formed in a ceiling surface of the chamber 210 to supply an inert gas such as nitrogen gas to the inside of the chamber 210. A gas supply line 213 communicating with a gas source 212 is connected to the gas supply port 211. A supply device group 214 including a valve and a flow rate controller for controlling a flow of the inert gas is provided in the gas supply line 213.

A suction port 215 is formed in a bottom surface of the chamber 210 to suck in an atmosphere inside the chamber 210. A negative pressure generating device 216 that generates a negative pressure is connected to the suction port 215. The negative pressure generating device 216 is, by way of example, a vacuum pump.

A heating section 220 and a temperature adjustment section 221 are located inside the chamber 210. The heating section 220 heats the device substrate W, the support substrate S, or the combined substrate T. The temperature adjustment section 221 adjusts the temperature of the device substrate W, the support substrate S, or the combined substrate T. The heating section 220 and the temperature adjustment section 221 are arranged along, for example, the Y-axis direction.

The heating section 220 has a hot plate 230, a holding member 231, and a support ring 232. The hot plate 230 has a thick, approximately circular plate shape, and is capable of heating the device substrate W, the support substrate S, or the combined substrate T placed thereon.

Also, the hot plate 230 is provided with, for example, a heater 233. The heating temperature of the hot plate 230 is controlled by, for example, the controller 5 (see FIG. 1), and the device substrate W, the support substrate S, or the combined substrate T placed on the hot plate 230 is heated to a required temperature.

The holding member 231 is of a ring shape, and is configured to hold an outer periphery of the hot plate 230 fitted therein. The support ring 232 is of an approximately cylindrical shape, and surrounds an outer periphery of the holding member 231.

A plurality of (e.g., three) support pins 240 are positioned below the hot plate 230. The support pins 240 support the device substrate W, the support substrate S, or the combined substrate T from below, and serves to raise and lower them. The support pins 240 can be moved up and down by an elevational driver 241.

A plurality of (e.g., three) through holes 242 are formed through the hot plate 230 in a thickness direction near the center of the hot plate 230. The support pins 240 are configured to be protrusible from a top surface of the hot plate 230 through the through holes 242.

The temperature adjustment section 221 has a temperature adjustment plate 250. The temperature adjustment plate 250 has a substantially rectangular flat plate shape as shown in FIG. 9, and its end surface on the hot plate 230 side is curved in an arc shape. Two slits 251 are formed at the temperature adjustment plate 250 along the Y-axis direction.

The slits 251 are formed from the end surface of the temperature adjustment plate 250 on the hot plate 230 side to near the center of the temperature adjustment plate 250. These slits 251 suppress the temperature adjustment plate 250 from interfering with the support pins 240 of the heating section 220 and support pins 260 of the temperature adjustment section 221 to be described later.

The temperature adjustment plate 250 is also provided with a temperature adjustment member (not shown), such as a Peltier element, embedded therein. The cooling temperature of the temperature adjustment plate 250 is controlled by the controller 5, and the device substrate W, the support substrate S, or the combined substrate T placed on the temperature adjustment plate 250 is cooled to a preset temperature.

The temperature adjustment plate 250 is supported by a support arm 252, as shown in FIG. 8. The support arm 252 is provided with a driver 253. The driver 253 is mounted to a rail 254 extending in the Y-axis direction.

The rail 254 extends from the temperature adjustment section 221 to the heating section 220. The driver 253 allows the temperature adjustment plate 250 to be movable along the rail 254 between the heating section 220 and the temperature adjustment section 221.

A plurality of (for example, three) support pins 260 are positioned below the temperature adjustment plate 250. The plurality of support pins 260 support the device substrate W, the support substrate S, or the combined substrate T from below, and serves to raise and lower them. The support pins 260 can be moved up and down by an elevational driver 261. The support pins 260 are configured to be protrusible from a top surface of the temperature adjustment plate 250 through the slits 251.

In the heat treating apparatus 41 configured as described above, when the device substrate W, the support substrate S or the combined substrate T is carried into the chamber 210 by the second transfer device 61 (see FIG. 1) in the second transfer section 60, the carried substrate is received by the support pins 260, which have been raised and held in standby in advance.

Next, the heat treating apparatus 41 lowers the support pins 260, allowing the device substrate W, the support substrate S or the combined substrate T to be placed on the temperature adjustment plate 250.

Then, the heat treating apparatus 41 moves the temperature adjustment plate 250 along the rail 254 by the driver 253 to above the hot plate 230, and hands the device substrate W, the support substrate S or the combined substrate T over onto the support pins 240 that have been raised and standing by in advance.

Subsequently, the heat treating apparatus 41 lowers the support pins 240, allowing the device substrate W, the support substrate S, or the combined substrate T to be placed on the hot plate 230. Then, the device substrate W, the support substrate S, or the combined substrate T on the hot plate 230 is heated to a preset temperature.

Thereafter, the heat treating apparatus 41 raises the support pins 240 and moves the temperature adjustment plate 250 to above the hot plate 230. Then, the heat treating apparatus 41 passes the device substrate W, the support substrate S, or the combined substrate T from the support pins 240 onto the temperature adjustment plate 250, and moves the temperature adjustment plate 250 to the second transfer section 60 side. During this movement of the temperature adjustment plate 250, the device substrate W, the support substrate S, or the combined substrate T is adjusted to a required temperature.

### Bonding Apparatus

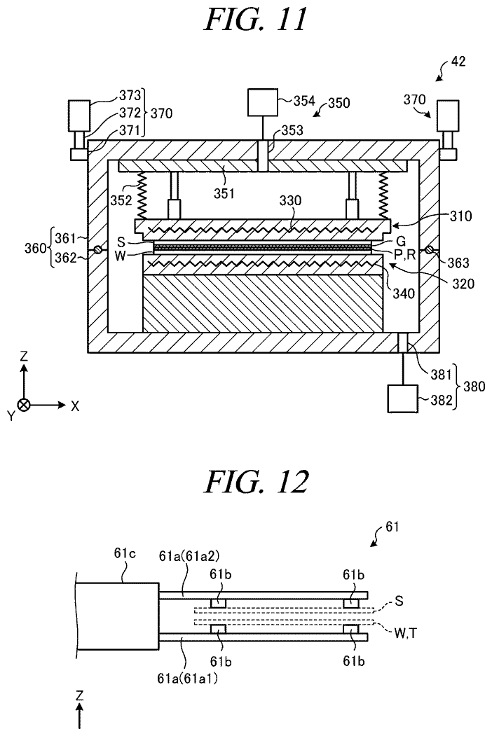

Now, a configuration of the bonding apparatus 42 will be explained with reference to FIG. 10 and FIG. 11. FIG. 10 and FIG. 11 are schematic cross sectional views illustrating an example configuration of the bonding apparatus 42 according to the exemplary embodiment.

As depicted in FIG. 10, the bonding apparatus 42 includes a first holder 310 and a second holder 320. The first holder 310 is positioned above the second holder 320 to face the second holder 320.

The first holder 310 and the second holder 320 are, for example, electrostatic chucks, and hold the support substrate S and the device substrate W by electrostatic attraction, respectively. The first holder 310 holds the support substrate S from above, and the second holder 320 holds the device substrate W from below.

The support substrate S and the device substrate W are held by the first holder 310 and the second holder 320, respectively, with the bonding surface Sj (see FIG. 2) and the bonding surface Wj (see FIG. 2) facing each other.

The first holder 310 and the second holder 320 may have vacuum attraction devices configured to vacuum-attract the support substrate S and the device substrate W, respectively, in addition to electrostatic attraction devices configured to electrostatically attract the support substrate S and the device substrate W, respectively.

The bonding apparatus 42 further includes a first heating mechanism 330, a second heating mechanism 340, and a pressing mechanism 350. The first heating mechanism 330 is embedded in the first holder 310, and serves to heat the first holder 310 to heat the support substrate S held by the first holder 310 to a preset temperature.

The second heating mechanism 340 is embedded in the second holder 320, and serves to heat the second holder 320 to heat the device substrate W held by the second holder 320 to a preset temperature.

The pressing mechanism 350 moves the first holder 310 vertically downwards, brining the support substrate S into contact with the device substrate W while pressing the support substrate S against the device substrate W. The pressing mechanism 350 has a base member 351, a pressure vessel 352, a gas supply line 353, and a gas source 354. The base member 351 is attached to a ceiling surface inside a first chamber member 361 to be described later.

The pressure vessel 352 is made of, by way of example, a stainless steel bellows configured to be expandable and contractible in a vertical direction. A lower end of the pressure vessel 352 is fixed to a top surface of the first holder 310, and an upper end thereof is fixed to a bottom surface of the base member 351.

One end of the gas supply line 353 is connected to the pressure vessel 352 via the base member 351 and the first chamber member 361 to be described later, and the other end thereof is connected to the gas source 354.

As a gas is supplied from the gas source 354 into the pressure vessel 352 via the gas supply line 353, the pressure vessel 352 is expanded so the first holder 310 is lowered.

As a result, the support substrate S comes into contact with the device substrate W and is pressed against it. The pressing force applied to the support substrate S and the device substrate W is adjusted by adjusting the pressure of the gas supplied to the pressure vessel 352.

The bonding apparatus 42 is also equipped with a chamber 360, a moving mechanism 370, a decompressing device 380, a first imaging device 391, and a second imaging device 392.

The chamber 360 is a processing vessel with a hermetically sealable inside, and includes the first chamber member 361 and a second chamber member 362. The first chamber member 361 is a cylindrical container with an open bottom, and accommodates the first holder 310, the pressure vessel 352, and the like. The second chamber member 362 is a cylindrical container with an open top, and accommodates the second holder 320, and the like.

The first chamber member 361 is configured to be vertically movable by a non-illustrated elevating mechanism such as an air cylinder. The elevating mechanism lowers the first chamber member 361 and brings the first chamber member 361 into contact with the second chamber member 362, forming a sealed space inside the chamber 360.

A seal member 363 is provided on a contact surface of the first chamber member 361 to be brought into contact with the second chamber member 362 to ensure airtightness of the chamber 360. By way of non-limiting example, an O-ring is used as the seal member 363.

The moving mechanism 370 is provided at an outer periphery of the first chamber member 361, and moves the first holder 310 horizontally via the first chamber member 361. The moving mechanism 370 is provided in plurality (for example, five) on the outer periphery of the first chamber member 361.

For example, four of the five moving mechanisms 370 are used to move the first holder 310 horizontally. Additionally, one of the five moving mechanisms 370 is used to rotate the first holder 310 around a vertical axis.

The moving mechanism 370 has a cam 371, a shaft 372, and a rotational driver 373. The cam 371 comes into contact with the outer periphery of the first chamber member 361 to move the first holder 310. The shaft 372 connects the cam 371 and the rotational driver 373. The rotational driver 373 rotates the cam 371 via the shaft 372.

The cam 371 is provided eccentrically with respect to the central axis of the shaft 372. In the moving mechanism 370, the cam 371 is rotated by the rotational driver 373, thereby moving the central position of the cam 371 relative to the first holder 310. This allows the moving mechanism 370 to move the first holder 310 horizontally.

The decompressing device 380 is provided at a lower portion of the second chamber member 362, for example, and serves to decompress the chamber 360. The decompressing device 380 has a suction line 381 and a suction device 382. The suction line 381 is provided to suck in an atmosphere inside the chamber 360. The suction device 382 is, for example, a vacuum pump, and is connected to the suction line 381.

Below the first holder 310, the first imaging device 391 images the front surface of the support substrate S held by the first holder 310. Above the second holder 320, the second imaging device 392 images the front surface of the device substrate W held by the second holder 320.

The first imaging device 391 and the second imaging device 392 are configured to be movable horizontally by a non-illustrated moving mechanism, respectively. The first imaging device 391 and the second imaging device 392 are advanced into the chamber 360 before the first chamber member 361 is lowered, and image the support substrate S and the device substrate W, respectively.

The imaging data of the first imaging device 391 and the second imaging device 392 are transmitted to the controller 5 (see FIG. 1). Each of the first imaging device 391 and the second imaging device 392 may be implemented by, for example, a wide-angle camera.

In the bonding apparatus 42 configured as described above, first, the support substrate S is held by the first holder 310, and the device substrate W is held by the second holder 320.

Subsequently, in the bonding apparatus 42, the first imaging device 391 and the second imaging device 392 shown in FIG. 10 are moved horizontally into the chamber 360, and image the surface of the support substrate S and the surface of the device substrate W, respectively.

Thereafter, the position of the support substrate S in the horizontal direction is adjusted by the moving mechanism 370 so that the position of the reference point of the support substrate S imaged by the first imaging device 391 coincides with the position of the reference point of the device substrate W imaged by the second imaging device 392. In this way, the position of the support substrate S relative to the device substrate W in the horizontal direction is adjusted.

Subsequently, after the first imaging device 391 and the second imaging device 392 are retreated from the chamber 360, the first chamber member 361 is lowered by the non-illustrated moving mechanism. Then, the first chamber member 361 comes into contact with the second chamber member 362, forming the sealed space inside the chamber 360.

Next, in the bonding apparatus 42, the atmosphere inside the chamber 360 is sucked in by the decompressing device 380, so that the chamber 360 is decompressed.

Thereafter, in the bonding apparatus 42, the support substrate S and the device substrate W are heated to the preset temperature (e.g., 200° C. to 250° C.) by the first heating mechanism 330 of the first holder 310 and the second heating mechanism 340 of the second holder 320, respectively.

Subsequently, in the bonding apparatus 42, by supplying a gas into the pressure vessel 352, the inside of the pressure vessel 352 is set to a preset pressure. As a result, as shown in FIG. 11, the first holder 310 is lowered, and the support substrate S and the device substrate W are pressed against each other under the preset pressure. As a result, the support substrate S and the device substrate W are bonded to each other.

### Second Transfer Device

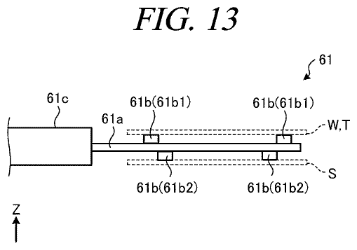

Now, a configuration of the second transfer device 61 will be explained with reference to FIG. 12 and FIG. 13. FIG. 12 is a schematic side view showing an example configuration of the second transfer device 61 according to the exemplary embodiment.

As illustrated in FIG. 12, the second transfer device 61 according to the exemplary embodiment includes a multiplicity of forks 61a, a multiple number of attracting mechanisms 61b, and an arm 61c. The fork 61a holds the device substrate W, the support substrate S, or the combined substrate T. The fork 61a has, for example, a bifurcated leading end when viewed from the top.

The attracting mechanism 61b is provided in plurality on each fork 61a, and serves to attract the device substrate W, the support substrate S, or the combined substrate T. The fork 61a attracts and holds the device substrate W, the support substrate S, or the combined substrate T by operating the plurality of attracting mechanisms 61b.

The arm 61c has a mechanism configured to move the fork 61a. In the example of FIG. 12, the single arm 61c moves the multiplicity of (e.g., two) forks 61a together.

The multiplicity of forks 61a include a first fork 61a1 and a second fork 61a2. The first fork 61a1 has the plurality of attracting mechanisms 61b on its top surface, and serves to hold the device substrate W or the combined substrate T from below.

The second fork 61a2 has the plurality of attracting mechanisms 61b on its bottom surface, and serves to hold the support substrate S coated with the adhesive G (see FIG. 2) from above.

As described above, in the present exemplary embodiment, the second transfer device 61 has two types of forks: the first fork 61a1 and the second fork 61a2. With this configuration, the device substrate W, which has been aligned by the alignment apparatus 73 (see FIG. 4), can be directly transferred to the bonding apparatus 42 (see FIG. 3), and the support substrate S, which has been inverted and aligned by the inversion alignment apparatus 72 (see FIG. 4), can be directly transferred to the bonding apparatus 42.

Therefore, according to the exemplary embodiment, the transfer efficiency of the device substrate W and the support substrate S can be improved. Further, in the present disclosure, the support substrate S may be held from below by the first fork 61a1.

Furthermore, the second transfer device 61 according to the exemplary embodiment is not limited to the example shown in FIG. 12. FIG. 13 is a schematic side view showing another example configuration of the second transfer device 61 according to the exemplary embodiment.

As depicted in FIG. 13, the second transfer device 61 as another example includes one fork 61a, a multiple number of attracting mechanisms 61b, and an arm 61c. In the example of FIG. 13, the multiple number of attracting mechanisms 61b include a plurality of first attracting mechanisms 61b1 and a plurality of second attracting mechanisms 61b2.

The plurality of first attracting mechanisms 61b1 are located on a top surface of the one fork 61a. The plurality of second attracting mechanisms 61b2 are located on a bottom surface of the same fork 61a.

With this configuration, as illustrated in FIG. 13, the second transfer device 61 is capable holding the device substrate W or the combined substrate T from below and capable of holding the support substrate S coated with the adhesive G (see FIG. 2) from above with the single fork 61a.

Therefore, the device substrate W, which has been aligned by the alignment apparatus 73 (see FIG. 4), can be directly transferred to the bonding apparatus 42 (see FIG. 3), and the support substrate S, which has been aligned and inverted by the inversion alignment apparatus 72 (see FIG. 4), can be directly transferred to the bonding apparatus 42.

Therefore, according to the example of FIG. 13, the transfer efficiency of the device substrate W and the support substrate S can be improved. Further, in the present disclosure, the support substrate S may be attracted and held from below by the plurality of first attracting mechanisms 61b1.

### Operation of Bonding System

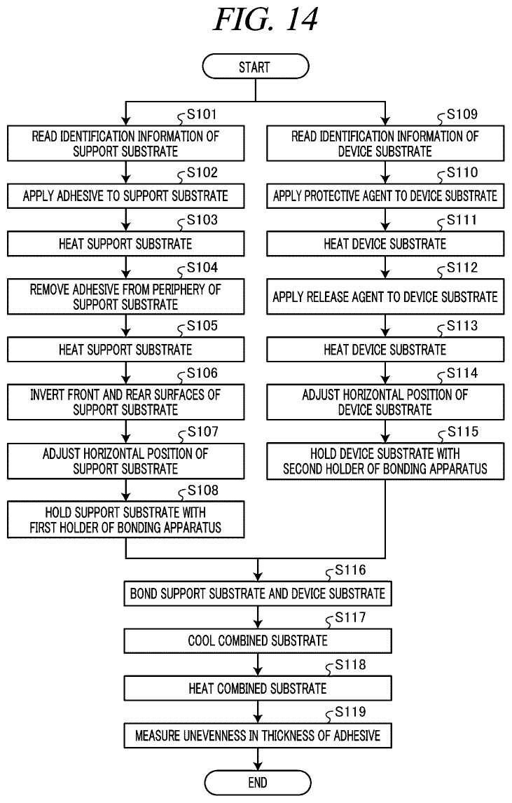

Now, an operation of the bonding system 1 described above will be discussed with reference to FIG. 14. FIG. 14 is a flowchart showing a sequence of a processing performed by the bonding system 1 according to the exemplary embodiment.

First, the controller 5 operates the first transfer device 24 to take out the support substrate S from the cassette C1 and transfer it to the ID reader 82 of the first inspection module 32 located in the third processing block G3. Then, the controller 5 operates the ID reader 82 to read the identification information of the support substrate S (process S101).

Next, the controller 5 operates the first transfer device 24 to take out the support substrate S from the ID reader 82 and transfer it to the delivery apparatus 74 of the delivery module 31 located in the third processing block G3. Then, the controller 5 operates the second transfer device 61 to take out the support substrate S from the delivery apparatus 74 and transfer it to the coating apparatus 51 located in the second processing block G2.

Furthermore, the controller 5 operates the coating apparatus 51 to apply the adhesive G to the bonding surface Sj of the support substrate S (process S102).

Next, the controller 5 operates the second transfer device 61 to take out the support substrate S coated with the adhesive G from the coating apparatus 51 and transfer it to the heat treating apparatus 41 located in the first processing block G1. Then, the controller 5 operates the heat treating apparatus 41 to heat the support substrate S to the preset temperature (process S103).

Next, the controller 5 operates the second transfer device 61 to take out the heat-treated support substrate S from the heat treating apparatus 41 and transfer it to the film thickness measurement apparatus 85 of the second inspection module 33 located in the first processing block G1. The controller 5 then operates the film thickness measurement apparatus 85 to measure the film thickness of the adhesive G applied on the support substrate S.

Here, the present disclosure is not limited to the case where the film thickness of the adhesive G is measured after the adhesive G is heat-treated, and the film thickness of the adhesive G may be measured before the adhesive G is heat-treated.

Next, the controller 5 operates the second transfer device 61 to take out the support substrate S from the film thickness measurement apparatus 85 and transfer it to the coating apparatus 51 located in the second processing block G2. Then, the controller 5 operates the coating apparatus 51 to remove the adhesive G from the periphery of the support substrate S (process S104).

Thereafter, the controller 5 operates the second transfer device 61 to take out the support substrate S with the adhesive G removed from its periphery from the coating apparatus 51 and transfer it to the heat treating apparatus 41 located in the first processing block G1. Then, the controller 5 operates the heat treating apparatus 41 to heat the support substrate S to the preset temperature (process S105).

Subsequently, the controller 5 operates the second transfer device 61 to take out the support substrate S from the heat treating apparatus 41 and transfer it to the periphery inspection apparatus 86 of the second inspection module 33 located in the first processing block G1. Then, the controller 5 operates the periphery inspection apparatus 86 to measure the state of the adhesive G removed from the periphery of the support substrate S.

Here, the present disclosure is not limited to the case where the state of the adhesive G removed from the periphery of the support substrate S is measured after the support substrate S is heat-treated, and the state of the adhesive G removed from the periphery of the support substrate S may be measured before the support substrate S is heat-treated.

Next, the controller 5 operates the second transfer device 61 to take out the support substrate S from the periphery inspection apparatus 86 and transfer it to the inversion alignment apparatus 72 of the delivery module 31 located in the third processing block G3.

Then, the controller 5 operates the inversion alignment apparatus 72 to invert the support substrate S (process S106). Furthermore, the controller 5 operates the inversion alignment apparatus 72 to adjust the horizontal position of the support substrate S (process S107).

Next, the controller 5 operates the second transfer device 61 to take out the support substrate S, whose front and rear surfaces have been inverted and whose horizontal position has been adjusted, from the inversion alignment apparatus 72 and transfer it to the bonding apparatus 42 located in the first processing block G1. Then, the controller 5 operates the bonding apparatus 42 to hold the support substrate S with the first holder 310 of the bonding apparatus 42 (process S108).

In parallel with the processing of the processes S101 to S108 described above, the controller 5 performs a processing of processes S109 to S115, which will be described below.

First, the controller 5 operates the first transfer device 24 to take out the device substrate W from the cassette C2 and transfer it to the ID reader 82 of the first inspection module 32 located in the third processing block G3. Then, the controller 5 operates the ID reader 82 to read the identification information of the device substrate W (process S109).

Next, the controller 5 operates the first transfer device 24 to take out the device substrate W from the ID reader 82 and transfer it to the delivery apparatus 74 of the delivery module 31 located in the third processing block G3. Then, the controller 5 operates the second transfer device 61 to take out the device substrate W from the delivery apparatus 74 and transfer it to the coating apparatus 51 located in the second processing block G2.

Also, the controller 5 operates the coating apparatus 51 to apply the protective agent P to the bonding surface Wj of the device substrate W (process S110).

Next, the controller 5 operates the second transfer device 61 to take out the device substrate W coated with the protective agent P from the coating apparatus 51 and transfer it to the heat treating apparatus 41 located in the first processing block G1. Then, the controller 5 operates the heat treating apparatus 41 to heat the device substrate W to a preset temperature (process S111).

Thereafter, the controller 5 operates the second transfer device 61 to take out the heat-treated device substrate W from the heat treating apparatus 41 and transfer it to the coating apparatus 51 located in the second processing block G2. Then, the controller 5 operates the coating apparatus 51 to coat the surface of the protective agent P applied in the process S110 with the release agent R (process S112).

Subsequently, the controller 5 operates the second transfer device 61 to take out the device substrate W coated with the release agent R from the coating apparatus 51 and transfer it to the heat treating apparatus 41 located in the first processing block G1. Then, the controller 5 operates the heat treating apparatus 41 to heat the device substrate W to a preset temperature (process S113).

Next, the controller 5 operates the second transfer device 61 to take out the device substrate W from the heat treating apparatus 41 and transfer it to the alignment apparatus 73 of the delivery module 31 located in the third processing block G3. Then, the controller 5 operates the alignment apparatus 73 to adjust the horizontal position of the device substrate W (process S114).

Next, the controller 5 operates the second transfer device 61 to take out the device substrate W whose horizontal position has been adjusted from the alignment apparatus 73 and transfer it to the bonding apparatus 42 located in the first processing block G1. Then, the controller 5 operates the bonding apparatus 42 to hold the device substrate W with the second holder 320 of the bonding apparatus 42 (process S115).

Next, the controller 5 operates the bonding apparatus 42 to bond the support substrate S held by the first holder 310 and the device substrate W held by the second holder 320 to form a combined substrate T (process S116).

Next, the controller 5 operates the second transfer device 61 to take out the combined substrate T formed in the process S116 from the bonding apparatus 42 and transfer it to the cooling apparatus 75 of the delivery module 31 located in the third processing block G3. Then, the controller 5 operates the cooling apparatus 75 to cool the combined substrate T to a preset temperature (process S117).

Then, the controller 5 operates the second transfer device 61 to take out the cooled combined substrate T from the cooling apparatus 75 and transfer it to the heat treating apparatus 41 located in the first processing block G1. Then, the controller 5 operates the heat treating apparatus 41 to heat the combined substrate T to a preset temperature (process S118).

Thereafter, the controller 5 operates the second transfer device 61 to take out the combined substrate T from the heat treating apparatus 41 and transfer it to the delivery apparatus 74 of the delivery module 31 located in the third processing block G3. Then, the controller 5 operates the first transfer device 24 to take out the combined substrate T from the delivery apparatus 74 and transfer it to the thickness measurement apparatus 81 of the first inspection module 32 located in the third processing block G3.

Also, the controller 5 operates the thickness measurement apparatus 81 to measure unevenness in the thickness of the adhesive G on the combined substrate T (process S119).

Subsequently, the controller 5 operates the first transfer device 24 to take out the combined substrate T from the thickness measurement apparatus 81 and transfer it to the periphery measurement apparatus 84 of the first inspection module 32. Then, the controller 5 operates the periphery measurement apparatus 84 to measure the periphery of the combined substrate T and observe the bonding state of the combined substrate T.

Finally, the controller 5 operates the first transfer device 24 to take out the combined substrate T from the periphery measurement apparatus 84 and place it in the cassette C3, thereby ending the series of processes.

The bonding system 1 according to the exemplary embodiment includes the processing station 3 and the carry-in/out station 2. The processing station 3 performs a preset processing on the first substrate (the support substrate S) and the second substrate (the device substrate W). The carry-in/out station 2 carries the first substrate (the support substrate S), the second substrate (the device substrate W), and the combined substrate T formed by bonding the first substrate (the support substrate S) and the second substrate (the device substrate W) to/from the processing station 3. The processing station 3 has the transfer device (the second transfer device 61), the delivery module 31, the coating apparatus 51, the bonding apparatus 42, and the heat treating apparatus 41. The transfer device (the second transfer device 61) transfers the first substrate (the support substrate S), the second substrate (the device substrate W), and the combined substrate T. The delivery module 31 delivers the first substrate (the support substrate S), the second substrate (the device substrate W), and the combined substrate T between the carry-in/out station 2 and the transfer device (the second transfer device 61). The coating apparatus 51 applies the adhesive G to the first substrate (the support substrate S). The bonding apparatus 42 bonds the first substrate (the support substrate S) coated with the adhesive G and the second substrate (the device substrate W) together to form the combined substrate T. The heat treating apparatus 41 heat-treats the first substrate (the support substrate S), the second substrate (the device substrate W), and the combined substrate T. The heat treating apparatus 41 and the bonding apparatus 42 are arranged in the stacked manner. With this configuration, the footprint of the bonding system 1 can be reduced.

In addition, in the bonding system 1 according to the exemplary embodiment, the heat treating apparatus 41 is disposed on the bonding apparatus 42. With this configuration, the bonding processing in the bonding apparatus 42 can be performed with high precision.

Furthermore, in the bonding system 1 according to the exemplary embodiment, the heat treating apparatus 41 and the bonding apparatus 42 are located on the first side 60a of the transfer section (the second transfer section 60) in which the transfer device (the second transfer device 61) is located. In addition, the coating apparatus 51 is located on the second side 60b opposite the first side 60a in the transfer section (the second transfer section 60). With this configuration, the adhesive G, the protective agent P, or the release agent R can be applied with high precision.

In addition, in the bonding system 1 according to the exemplary embodiment, the delivery module 31 has the inversion alignment apparatus 72 configured to invert the first substrate (the support substrate S) upside down and align the first substrate (the support substrate S). With this configuration, the footprint of the bonding system 1 can be further reduced.

Further, in the bonding system 1 according to the exemplary embodiment, the delivery module 31 has the alignment apparatus 73 configured to align the second substrate (the device substrate W). With this configuration, the footprint of the bonding system 1 can be further reduced.

In addition, in the bonding system 1 according to the exemplary embodiment, the delivery module 31 has the cooling apparatus 75 configured to cool the combined substrate T. With this configuration, the footprint of the bonding system 1 can be further reduced.

Furthermore, in the bonding system 1 according to the exemplary embodiment, the carry-in/out station 2 has another transfer device (the first transfer device 24) configured to transfer the first substrate (the support substrate S), the second substrate (the device substrate W), and the combined substrate T between the plurality of cassettes C and the delivery module 31. Further, the processing station 3 has the inspection module (the first inspection module 32) configured to inspect at least one of the first substrate (the support substrate S), the second substrate (the device substrate W), and the combined substrate T. The inspection module (the first inspection module 32) cannot be accessed from the transfer device (the second transfer device 61), but can only be accessed from the another transfer device (first transfer device 24). With this configuration, the footprint of the bonding system 1 can be further reduced.

Moreover, in the bonding system 1 according to the exemplary embodiment, the inspection module (the first inspection module 32) has the thickness measurement apparatus 81 configured to measure unevenness in the thickness of the adhesive G on the combined substrate T. With this configuration, the footprint of the bonding system 1 can be further reduced.

Additionally, in the bonding system 1 according to the exemplary embodiment, the inspection module (the first inspection module 32) has the ID reader 82 configured to read the identification information assigned to the first substrate (the support substrate S) and the second substrate (the device substrate W). With this configuration, the footprint of the bonding system 1 can be further reduced.

So far, the exemplary embodiment of the present disclosure has been described. However, the present disclosure is not limited to the above-described exemplary embodiment, and various changes and modifications may be made without departing from the spirit of the present disclosure. By way of example, although the exemplary embodiment has been described for the example where the bonding processing is performed in the state where the support substrate S is held by the first holder 310 and the device substrate W is held by the second holding holder 320 in the bonding apparatus 42, the present disclosure is not limited to such an example.

For example, in the present disclosure, the bonding processing may be performed in a state where the device substrate W is held by the first holder 310 and the support substrate S is held by the second holder 320 in the bonding apparatus 42. This configuration also allows the bonding processing between the support substrate S and the device substrate W to be performed successfully.

Further, the exemplary embodiment has been described for the example where the device substrate W is bonded to the support substrate S after being coated with the protective agent P and the release agent R. However, the present disclosure is not limited to such an example, and the protective agent P, for example, may be omitted.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

According to the exemplary embodiment, it is possible to reduce the footprint of the bonding system. It should also be noted that the effects described herein are not necessarily limited thereto and may be any one of the effects described in the present disclosure.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

We claim

1. A bonding system, comprising:
a processing station configured to perform a required processing on a first substrate and a second substrate; and
a carry-in/out station configured to carry the first substrate, the second substrate, and a combined substrate, which is formed by bonding the first substrate and the second substrate, to/from the processing station,
wherein the processing station comprises:
a transfer device configured to transfer the first substrate, the second substrate, and the combined substrate;
a delivery module including a holder and configured to deliver the first substrate, the second substrate, and the combined substrate between the carry-in/out station and the transfer device;
a coating apparatus configured to apply an adhesive to the first substrate;
a bonding apparatus configured to bond the first substrate coated with the adhesive and the second substrate to form the combined substrate; and
a heat treating apparatus configured to heat-treat the first substrate, the second substrate, and the combined substrate, and
the heat treating apparatus and the bonding apparatus are arranged in a stacked manner.

2. The bonding system of claim 1,
wherein the heat treating apparatus is disposed above the bonding apparatus.

3. The bonding system of claim 1,
wherein the processing station includes a transfer section,
the heat treating apparatus and the bonding apparatus are located on a first side of the transfer section in which the transfer device is located, and
the coating apparatus is located on a second side of the transfer section, opposite the first side.

4. The bonding system of claim 1,
wherein the delivery module comprises an inversion alignment apparatus configured to invert the first substrate upside down and align the first substrate.

5. The bonding system of claim 1,
wherein the delivery module comprises an alignment apparatus configured to align the second substrate.

6. The bonding system of claim 1,
wherein the delivery module comprises a cooling apparatus configured to cool the combined substrate.

7. The bonding system of claim 1,
wherein the carry-in/out station comprises another transfer device configured to transfer the first substrate, the second substrate, and the combined substrate between multiple cassettes and the delivery module,
the processing station comprises an inspector configured to inspect at least one of the first substrate, the second substrate, or the combined substrate, and
the inspector is not accessible from the transfer device, and is only accessible from the another transfer device.

8. The bonding system of claim 7,
wherein the inspector comprises a thickness measurement apparatus configured to measure unevenness of a thickness of the adhesive in the combined substrate.

9. The bonding system of claim 7,
wherein the inspector comprises an ID reader configured to read identification information assigned to the first substrate and the second substrate.

10. The bonding system of claim 1, wherein the processing station comprises a plurality of heat treating apparatuses stacked above a plurality of bonding apparatuses.

11. The bonding system of claim 1, wherein the coating apparatus further comprises a periphery cleaner configured to remove adhesive from a peripheral portion of the first substrate.

12. The bonding system of claim 7, wherein the processing station further comprises a second inspector including:
a film thickness measurement apparatus configured to measure unevenness of a thickness of the adhesive in the combined substrate; and
a periphery inspection apparatus to measure the state of the adhesive removed from the periphery of the support substrate.

13. A method of bonding substrates using a bonding system, comprising:
carrying a first substrate and a second substrate into a processing station via a carry-in/out station;
applying an adhesive to the first substrate using a coating apparatus;
heat-treating the first substrate using a heat treating apparatus; aligning and inverting the first substrate using a delivery module;
bonding the first substrate and the second substrate to form a combined substrate using a bonding apparatus stacked with the heat treating apparatus;
cooling and inspecting the combined substrate; and
carrying out the combined substrate.

14. The method of claim 13,
wherein the heat treating apparatus is disposed above the bonding apparatus.

15. The method of claim 13,
wherein the processing station includes a transfer section,
the heat treating apparatus and the bonding apparatus are located on a first side of the transfer section in which the transfer device is located, and
the coating apparatus is located on a second side of the transfer section, opposite the first side.

16. The method of claim 13, further comprising inverting the first substrate upside down and aligning the first substrate, using an inversion alignment apparatus of the delivery module.

17. The method of claim 13, further comprising aligning the second substrate using an alignment apparatus of the delivery module.

18. The method of claim 13, wherein the combined substrate is cooled by a cooling apparatus of the delivery module.

19. The method of claim 13, further comprising:
transferring the first substrate, the second substrate, and the combined substrate between multiple cassettes and the delivery module, by another transfer device of the carry-in/out station; and
inspecting at least one of the first substrate, the second substrate, or the combined substrate by an inspector of the processing station,
wherein the inspector is not accessible from the transfer device, and is only accessible from the another transfer device.

20. A non-transitory computer-readable recording medium storing a program that, when executed by circuitry of a bonding system, causes the bonding system to:
control a transfer device to transfer a first substrate and a second substrate;
apply an adhesive to the first substrate via a coating apparatus;
heat-treat substrates via a stacked heat treating apparatus;
bond the substrates via a bonding apparatus; and
inspect the combined substrate via an inspector accessible only from a specific transfer device.
